(19) United States
(12) Patent Application Publication
(10) Pub. No.: US 2007/0075753 A1
(43) Pub. Date: Apr. 5, 2007

(54) Duty cycle measurement circuit

(76) Inventors: Rachael Parker, Forest Grove, OR (US); Mark Neidengard, Hillsborro, OR (US); Shamsul Abedin, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/240,761

(22) Filed: Sep. 30, 2005

(51) Int. Cl. H03B 19/00

(52) U.S. Cl. 327/116

(57) ABSTRACT

A duty cycle measurement circuit and method of operation is described that is particularly well adapted for use in microelectronics devices. In one embodiment, the circuit the includes a clock signal selector to alternately select the high or the low phase of an input clock signal, a sweep circuit to sweep a timing parameter through a range, and a latch to compare the clock signal to the timing parameter and generate a result.

### FIELD

The present description relates to measuring the duty cycle of a clock in a microelectronic circuit and, in particular, to measuring the duty cycle offset of a clock using a half-cycle timing path.

### BACKGROUND

Microelectronic circuits typically rely on clock circuits to control the timing of most operations. The timing will be generated from a central clock and then distributed to thousands of different clock pins for different circuits. This allows operations to be synchronized and it slows data to be communicated more effectively. With faster circuits and double data rate components, the duty cycle of the clock may be as important as the speed of the clock. A double data rate circuit responds to the positive portion as well as the negative portion of the clock. Typically, this means the rising and the falling edges of a clock pulse. Operations may be negatively affected if these two edges are not evenly spaced. In a complex microelectronic system, clock signals may be affected by jitter in phase locked loops and clock distribution circuits, by skew in the clock distribution circuits, by temperature changes, and by a variety of different noise sources, including the power supply.

In order to maintain a consistent duty cycle in a clock signal, the duty cycle may be measured. For accuracy, such a measurement circuit should be able to directly measure the duty cycle over a range of frequencies and delays. The measurement circuit should also be able to measure the duty cycle with a high accuracy and a small number of components, i.e. a low gate count. One difficulty in semiconductor systems is to design a circuit that will be accurate over process variations. In other words, the physical characteristics of each gate are a little different on each chip and in different places on each chip because of the inaccuracies in the photolithography, chemical, and physical processes used to make the chip. These variations make it difficult to obtain high accuracy with conventional systems.

### BRIEF DESCRIPTION OF THE DRAWINGS

Embodiments of the present invention will be understood more fully from the detailed description given below and from the accompanying drawings of various embodiments of the invention. The drawings, however, should not be taken to be limiting, but are for explanation and understanding only.

FIG. 1 is a circuit diagram of a duty cycle monitor according to an embodiment of the invention;

FIG. 2 is a circuit diagram of a duty cycle monitor according to another embodiment of the invention;

FIG. 3 is a process flow diagram of measuring a duty cycle by sweeping through delay according to an embodiment of the invention;

FIG. 4 is a process flow diagram of measuring a duty cycle by sweeping through frequency according to an embodiment of the invention;

FIG. 5 is block diagram of a microelectronic device with a duty cycle monitor according to an embodiment of the invention;

FIG. 6 is a circuit diagram of an alternative to the XOR device of FIGS. 1 and 2 according to an embodiment of the invention; and

FIG. 7 is an example of a computer system capable of performing aspects of the present invention.

### DETAILED DESCRIPTION

Embodiments of the present invention allow the duty cycle of any signal on a microelectronic circuit to be measured, including a core clock. A half-cycle timing path with an adjustable setup margin may be combined with an ability to select between the high-phase and the low-phase half cycles of the measured signal. “Setup margin” may be considered to be the time difference or delta between when the input to a latch or flip-flop settles, and the time when the latch or flip-flop samples that input. A negative setup margin implies that the input has arrived too late to be sampled by the desired clock (e.g.) edge. While a positive setup margin implies that the input arrives early enough to be sampled by the clock rate edge.

If the setup margin is fixed, then the difference in sweeping across a range of frequencies at constant phase for the high-phase and low-phase cycles may be used to compute the duty cycle. Instead of a frequency shmoo, a delay smoo may be used. The frequency may be held constant and the delay swept through a range for the high-phase and low-phase portions of the signal. The differences may then be used to compute the duty cycle. Either one or both of these timing parameters may be swept to measure duty cycle, or other parameters may be used instead.

A duty cycle measurement circuit according to embodiments of the present invention may be used to measure the effects of temperature, voltage and process variations, whether random or systematic on the duty cycle of any signal. The results may be used to monitor and improve clock fidelity over a population of parts. Correcting the clock duty cycle may allow the maximum operating frequency of a microelectronic circuit to be increased by more than ten percent. Such a performance improvement is available without adding any other cost to the circuit and without any change in voltage or process. The duty cycle measurement may also be provided to a duty cycle adjustment circuit to adjust the clock duty cycle while the system is in use.

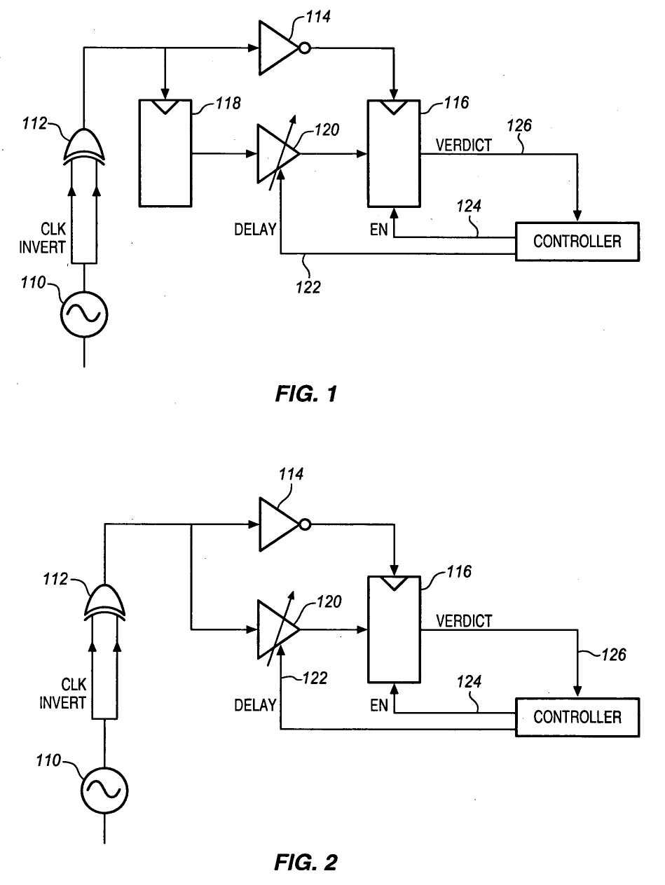

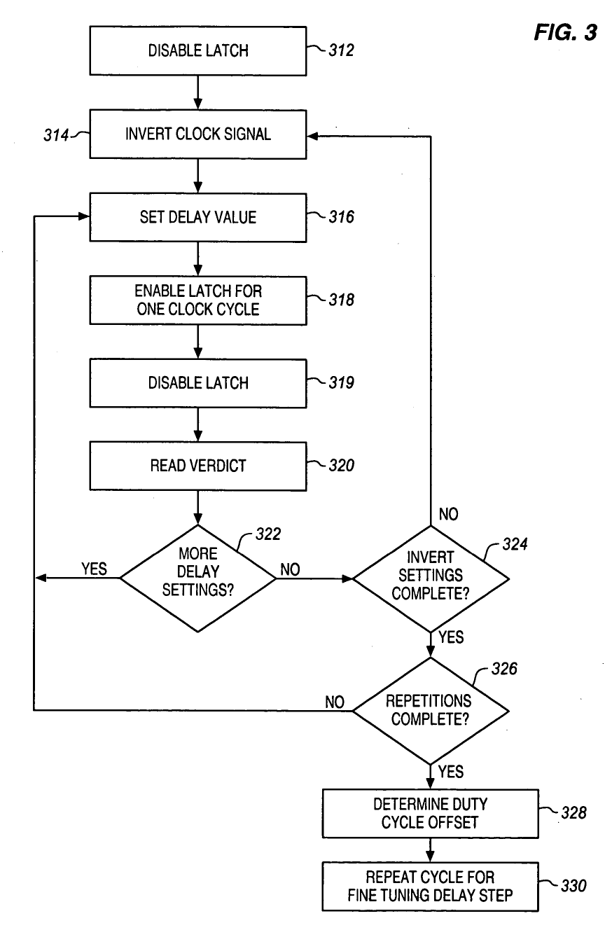

FIG. 1 shows a logical block diagram of a duty cycle measurement circuit according to an embodiment of the present invention. The circuit receives the clock signal 110 to be measured at a conditional invert unit 112. In the present example this is drawn as an XOR (exclusive OR) circuit. The conditional invert unit may be carefully designed to minimize shifts in the duty cycle between the inverted and non-inverted settings. Such a shift may corrupt the duty cycle measurement for the downstream measurement components. The conditional invert circuit may be constructed from a set of NAND gates or using a chain of inverters as shown in FIG. 3.

The output of the conditional invert circuit is passed to an inverter 114 and then to a latch circuit 116. The latch circuit is then triggered by the negative edge of the clock signal due to the inverter. The output of the conditional invert signal is also applied to a positive edge-triggered latch circuit 118. This latch circuit receives no other inputs and is used to initiate a half-cycle path. The output of the positive edge-triggered delay circuit is applied to a variable delay line 120, that receives a delay control signal 122 from an external control circuit 128.

The variable delay line output is applied to the negative edge-triggered latch circuit 116 to compare the two edges. The negative edge-triggered latch is also shown as receiving an EN (enable) input 124 from the external control circuit 128 and producing a verdict 126. The verdict may be applied to the control circuit 128 as shown, to an external interface (not shown) or to any other device. The verdict is the result of comparing the negative-edge signal from the inverter at the trigger input to the variable delay line input. Note that all of the components downstream of the conditional invert circuit operate in common mode with respect to the duty cycle.

By sweeping the delay of the variable delay line, and evaluating the verdict output, the difference between the negative edge and the positive edge may be measured. These edges indicate the duty cycle for each half cycle of the input clock signal.

For a frequency-based shmoo, the delay line may be empirically adjusted to have near 0 setup margin for one of the clock phases at the intended operating frequency. The frequency may then be adjusted from low to high in any fashion (for example linear steps) and then the frequency at which the measurement circuit's verdict switches for both settings of the invert signal may be noted. The duty cycle offset (DCO) may be defined as the duration of the high phase minus half the duration of a complete cycle. Assuming the DCO is independent of frequency, DCO=(1/Fnoninvert−1/Finvert)/4. The DCO may often vary with frequency, so for higher accuracy DCO determinations this factor may also be considered. For many systems, the frequency is kept within a narrow range and so this factor may be ignored.

FIG. 2 shows an alternative embodiment in which the positive edge-triggered latch is deleted. All of the other components are the same. Accordingly the output of the conditional clock invert unit 112 is applied directly to the variable delay line 120. This reduces the power and area required to support the measurement circuit. In addition, eliminating the latch also provides more measurement headroom. The maximum frequency at which measurements are possible is governed by the minimum delay from the conditional invert unit, through the delay lines, to the latch.

In one embodiment, the circuit designs of either FIG. 1 or FIG. 2 may be operated with a delay line that has both a coarse tuning section and a fine tuning section. For a core clock on the order of three to four GHz, a coarse step size may be about 20-30 ps and a fine step size may be about 2-3 ps per step. In this example, the fine-tunable range exceeds the coarse step size so that there are no unreachable values for the delay. The specific size of the steps may be selected to suit the operating speed and clock sensitivity of any particular microelectronic system.

FIG. 3 shows an example of applying a circuit such as that of FIG. 1 or FIG. 2 to measuring a duty cycle while sweeping through different delay values using the variable delay line. In the example of FIG. 3, such a measurement cycle begins by disabling the negative edge-triggered latch at block 312 using the EN control input 124. At block 314, the clock signal invert is set and at block 316, the variable delay value is set using the control input 122 to the variable delay gate. If the variable delay line allows for both coarse and fine delay settings, then the fine delay values may be fixed while the coarse delay value is varied. When a best coarse delay value is found, then the fine delay values may be varied

At block 318, the latch is enabled at its EN control input for one cycle of the core clock. At the completion of the clock cycle, the latch is disabled at block 319 and the verdict is then read from the output of the latch at block 320. In one embodiment, the verdict is a single bit to indicate a pass or a fail to the external control circuit.

The verdict bit may be used to indicate whether or not the delayed clock edge from the delay line settles at the latch's data terminal before (“pass”) or after (“fail”) the subsequent clock edge reaches the latch's data terminal. If the delayed clock edge settles at the latch terminal before the clock edge, then a pass verdict may be generated. If the delay line output is after the clock edge then a fail may be indicated. When the delay line is shmooed or swept from less to more delay, a verdict is generated for each delay value. This may be combined into a string of ones and zeroes, one for pass and zero for fail, to form a vector. If there are 19 delay line values tested, then such a vector may look like the following: 1111111111000000000. The index into the vector shows the shmoo setting at which the data was taken. The pass/fail boundary in this example vector is very clearly at the position at which the ones turn into zeroes. However, in the presence of noise that boundary may be obscured. So, for example, there are some zeroes before the last one and ones after the first zero or both. A more accurate result may be obtained using some, sort of repeated averaging to obtain the final answer. The additional cycles, sweeping, averaging and other post-processing may be performed in the external control circuit.

The circuit may then sweep through a range of delay settings, performing the same test through the latch each time. At block 322, if there are more delay settings through which to sweep, then the process returns to block 316. At block 316, a new variable delay line value is set and the test is repeated. When all the delay values have been tested, then the process moves to block 324. While a linear sweep of delay values may be used at block 316, other approaches are also possible. The delay values may be set in a staggered or stair step pattern. The delay line values may also be assigned in an iterative manner to converge on the boundaries sooner. Other patterns may be used to suit a particular implementation.

At block 324, the process determines whether both clock inversion settings (positive and negative) have been tested. The delay value verdict may be tested for a normal (positive) clock cycle and the inverted (negative) clock cycle. The comparison allows the positive part of the duty cycle to be compared to the negative part of the duty cycle. After the duty cycle for one portion of the clock signal is determined, then at block 324, the process returns to block 314 to reverse the inverter output and then the process of blocks 316 to 322 may be repeated for that cycle. After a coarse delay value for the opposite side of the clock has been determined, then from block 324, the process may move to determine whether all of the repetition cycles are completed at block 326. The measurements may be repeated over a large number of steps in order to average out any unusual clock pulses. If the repetitions are not complete then the process may return to block 316 for further repetitions. If the repetitions are complete, then the process may move to the next block.

At block 328, the delay sweep through all values on the positive and negative portions of the clock may be repeated for the fine tuning delay steps. In other words the tuning cycles of blocks 316 to 326 are repeated for the fine tuning delay steps. The particular range of steps may be selected based on the coarse tuning delay steps so that all of the fine tuning delay steps are within the two best coarse tuning steps.

At block 330, a duty cycle offset may be determined based on all of the measurements made for the positive and negative portions of the cycle, and through the entire sweep of delays. The duty cycle offset may be determined by the lowest phase delay setting that returned a pass verdict and then subtracting the highest phase delay setting that returned a pass verdict. When comparing sweep cycles from the non-inverted and the inverted measurements, a good set of verdicts may resemble the two vectors below:

111111110000000000

111111111111000000

This example pair of vectors shows that the high phase is four delay settings shorter than the low phase, and that the DCO is therefore (8−12)/2=−2 settings.

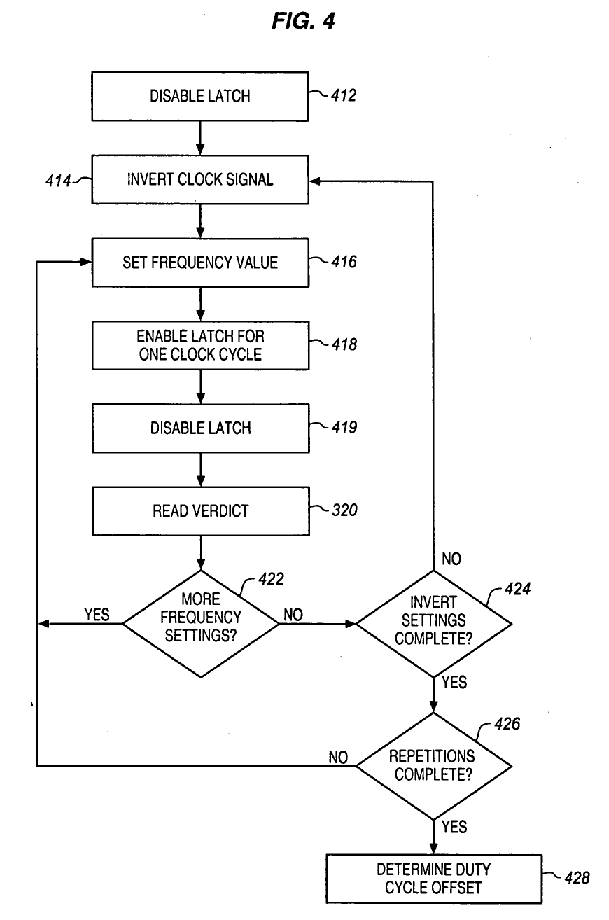

In one embodiment, only one verdict out of a string of verdicts is grabbed, that, is only one verdict per clock cycle. The operating frequency of the core clock may be a rational multiple NIM of the reference (i.e. bus) clock provided from off the chip. If, for example M=1, then there are N core clocks to every one reference clock. It may be the case that the i'th core clock of every reference clock period exhibits an abnormality, or that the j'th core clock within a particular bus, clock while executing a particular program, exhibits an anomaly. In order to detect such an anomaly if the tester hardware can only interact with the chip at reference-clock rates, then the duty cycle monitor circuit may include an ability to pick core clocks relative to the nearest reference clock edge. An alternative approach is shown in FIG. 4, in which a frequency shmoo is used instead of the delay shmoo of FIG. 3. FIG. 4 shows an example of applying a circuit such as that of FIG. 1 or FIG. 2 to measuring a duty cycle while sweeping through different frequency values by adjusting the distribution clock output frequency (typically by adjusting the core clock). In the example of FIG. 4, such a measurement cycle begins by disabling the negative edge-triggered latch at block 412 using the EN control input 124. At block 414, the clock signal invert is set and at block 416, the variable delay value is set using the control input 122 to the variable delay gate. For sweeping the frequency, the delay may be set to approximately half of the period of the desired input clock, for example.

At block 418, the latch is enabled at its EN control input for one cycle of the core clock. At the completion of the clock cycle, the latch is disabled at block 419 and the verdict is then read from the output of the latch at block 420. In one embodiment, the verdict is a single bit to indicate a pass or a fail to the external control circuit.

The circuit may then sweep through a range of input clock frequency settings, performing the same test through the latch each time. All with a fixed delay. At block 422, if there are more frequency settings through which to sweep, then the process returns to block 416. At block 416, a new frequency value is set and the test is repeated. When all the frequency values have been tested, then the process moves to block 424. As with the delay values, any pattern of frequency values may be used, including linear, staggered, iterative, or a stair step pattern.

At block 424, the process determines whether both clock inversion settings (positive and negative) have been tested. After the duty cycle for one portion of the clock signal is determined, then at block 424, the process returns to block 414 to reverse the inverter output and then the process of blocks 416 to 422 may be repeated for that cycle. After a frequency value for the opposite side of the clock has been determined, then from block 424, the process may move to determine whether all of the repetition cycles are completed at block 426. The measurements may be repeated over a large number of steps in order to average out any unusual clock pulses. If the repetitions are not complete then the process may return to block 416 for further repetitions. If the repetitions are complete, then the process may move to the next block.

At block 428, a duty cycle offset may be determined based on all of the measurements made for the positive and negative portions of the cycle, and through the entire sweep of frequencies. The duty cycle offset may be determined by, for example, averaging the highest and lowest passing frequencies.

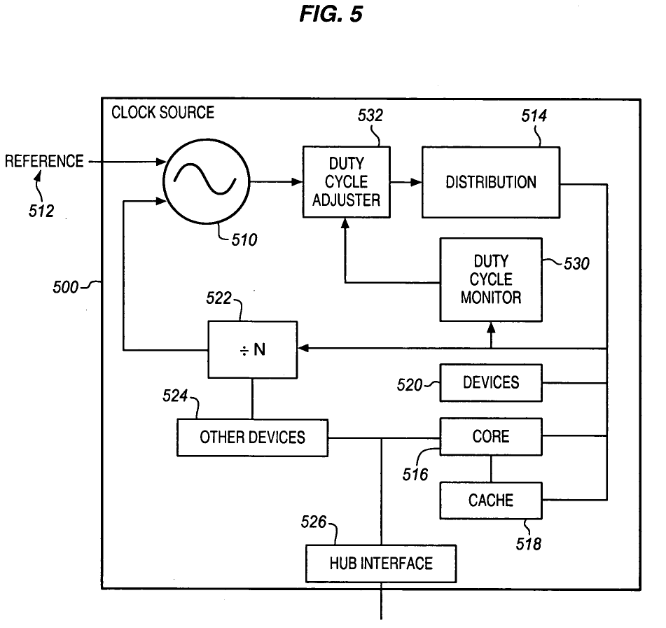

FIG. 5 shows an example of an application of the duty cycle measurement circuit of FIGS. 1 and 2. In FIG. 5, a reference clock source 510, such as a PLL is resident within a microelectronics device 500 which in this example is a microprocessor. The core clock is coupled to a reference clock 512 (not shown) such as a VCXO. The core clock is provided to a clock distribution circuit 514 which distributes the clock to any devices that are capable of using it. In the present example, the core clock frequency is distributed to a processing core 516, a memory cache 518 and other high speed devices indicated generically at block 520.

The core clock from the distribution circuit is also provided to a divider 522 which divides the clock into lower frequency clock pulses. The lower frequency clock may be provided to still further devices indicated generally by block 524. In the microprocessor example of FIG. 5, all of the clocked devices are coupled to a hub interface 526 that may be coupled to a memory or I/O hub. The hub interface may also receive a clock signal directly from the clock distribution block, or the divider, or indirectly through one of the other devices. From the clock divider 522, the clock pulse may be fed back into the clock source 510 as a clock feedback signal to compare with the reference clock.

A duty cycle monitor such as the one shown in FIG. 1 or FIG. 2 is coupled to the clock signal. The duty cycle monitor may include the external control circuit 128 for some implementations. The control connections, if any, are not shown in order to simplify the drawing. In the example of FIG. 5, the duty cycle monitor 530 is coupled between the distribution block 514 before the divider 522. By receiving the highest frequency clock source, higher accuracy may be obtained in the measurement cycles of e.g. FIGS. 3 and 4. However, one or more duty cycle monitor circuits may be coupled to the clock at any of a variety of different locations. In the configuration of FIG. 5, the duty cycle monitor may measure the effect on the core clock of temperature, voltage, and process variations. In one embodiment, the measurements from the duty cycle monitor circuit may be used to monitor and improve clock fidelity over a population of parts. As mentioned above, improving clock fidelity may allow for the operating clock speed of the corresponding components to be increased significantly.

In the example of FIG. 5, the results from the duty cycle monitor 530 are applied to a duty cycle adjuster 532. The duty cycle adjuster is connected to the output of the clock source 510 before the distribution block 514 to adjust the operation of the clock. A variety of different types of duty cycle adjusters may be used. In addition, or as an alternative, the results of the duty cycle monitor may be logged or provided on an output line for study and analysis in product development. As a further alternative, the results from the duty cycle monitor may be used to adjust the clock speed. When either phase becomes too short to be sustained by the system, then the clock speed may be reduced to increase the duration of both phases of each clock cycle.

In FIGS. 1 and 2, an Exclusive OR (XOR) circuit is shown for supplying the clock circuit and invert signal to the delay lines and latches. As described above, an XOR function is well-suited to this application and may be used as a conditional invert switch. In order to obtain the most accurate measurements by the duty cycle measurement circuit, distortions in the duty cycle introduced by the XOR should be minimized. A particular difficulty is in the invert mode of the XOR circuit in, for example, keeping the time when the output signal is low equal to the time that the input signal is low. This may be difficult because of imbalances in response between the p gates and the n gates.

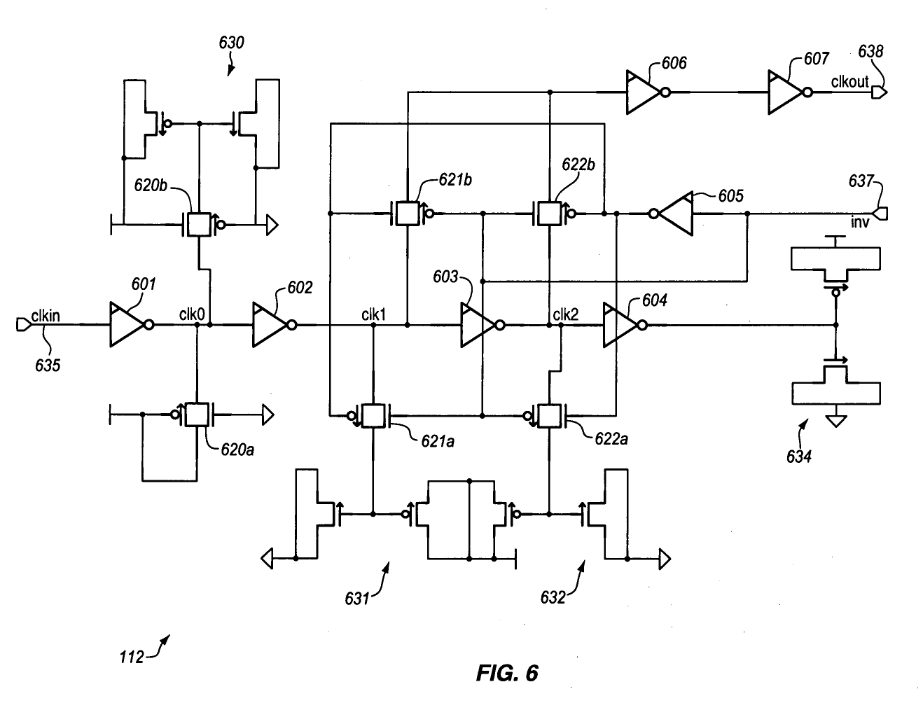

As an alternative to an XOR, typically constructed from a set of NAND gates, a chain of inverters chained to pass gates may be used as shown in FIG. 6. In the configuration of FIG. 6, each of the pass gates may be tuned in its design to null out imbalances between p gates and n gates. Like the XOR in FIGS. 1 and 2, the circuit of FIG. 6 has a clock input 635 and an invert input 637. These are used to generate a clock out circuit 638.

The clock input is applied to a linear chain of inverters 601, 602, 603, 604 used as loads and drivers. The output of the first three inverters clk0, clk1, clk2, respectively, are each coupled to respective pull-up and pull-down pass gates 620a, 620b, 621a, 621b, 622a, 622b. The pass gates are balanced, each using complementary N and P devices. The invert signal is applied to the second and third pair of pass gates as a control signal to select either clk 1 or clk 2 as the clkout signal 638. The selected signal is applied to a pair of inverters 606, 607 before the output that serve as drivers and loads to the pass gates. To select the output signal as either clk1 or clk2, the invert signal is coupled through an inverter 605 to gates of the third pair of pull-up and pull-down pass gates 622a, 622b and directly to gates of the second and third pair of pass gates 621a, 621b, 622a, 622b.

In order to balance out inconsistencies in the duty cycle of the various inverters and pass gates, a dummy load is applied to each inverter output signal. For clk0, clk1, and clk2, the dummy load is applied opposite a pass gate. The loads are made up of balanced n and p gates coupled across the gates of a pass gate. Clk3 is the output of the fourth inverter 604 in the chain. The fourth inverter 604 is used as a load for the third inverter 603. To provide a load for the fourth inverter 604 balanced n and p capacitors 634 may be used. The capacitors are designed to mimic the load that would be presented by another inverter.

It has been found that the switching time of each unit and a mismatch between p and n devices can cause significant distortions in the duty cycle. Slow switching times are related to high loads on the devices. Accordingly, a typical XOR circuit may introduce significant duty cycle imbalances. The circuit of FIG. 6 offers an alternative XOR design that may be optimized to reduce duty cycle imbalances, however, other approaches may be used to reduce these and other distortions. As can be seen in FIG. 6, the load on each inverter is kept small and very close to the load on each other inverter. The population of p and n devices is also well-balanced.

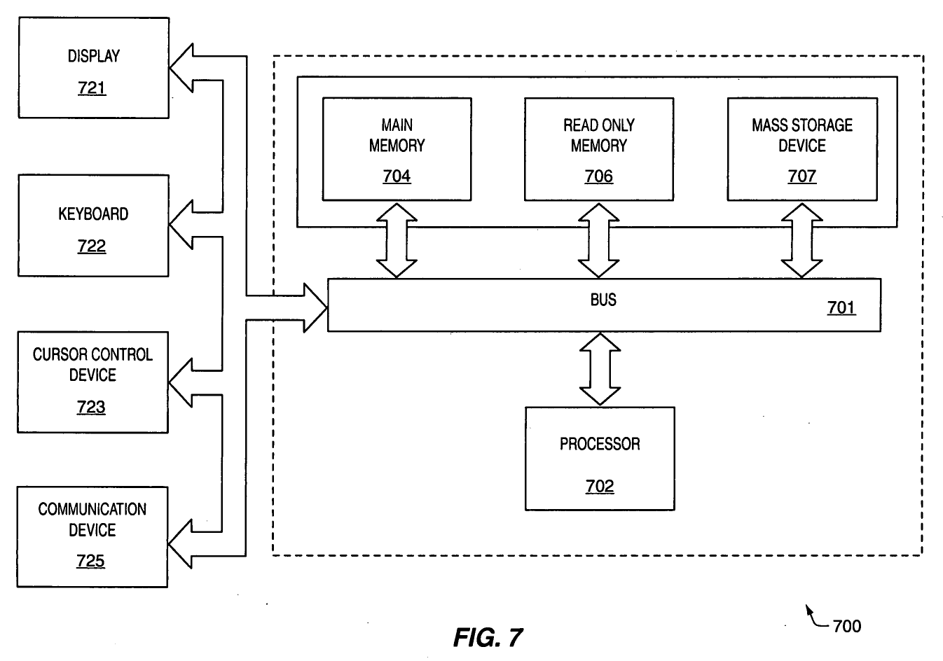

A computer system 700 representing an example of a system upon which features of the present invention may be implemented is shown in FIG. 7. The computer system 700 includes a bus or other communication means 701 for communicating information, and a processing means such as a microprocessor 702 coupled with the bus 701 for processing information. The microprocessor may be of the type shown in FIG. 5. The computer system 700 further includes a main memory 704, such as a random access memory (RAM) or other dynamic data storage device, coupled to the bus 701 for storing information and instructions to be executed by the processor 702. The main memory also may be used for storing temporary variables or other intermediate information during execution of instructions by the processor.

The computer system may also include a nonvolatile memory 706, such as a read only memory (ROM) or other static data storage device coupled to the bus for storing static information and instructions for the processor. A mass memory 707 such as a magnetic disk or optical disc and its corresponding drive may also be coupled to the bus of the computer system for storing information and instructions.

The computer system can also be coupled via the bus to a display device or monitor 721, such as a Liquid Crystal Display (LCD), for displaying information to a user. For example, graphical and textual indications of installation status, operations status and other information may be presented to the user on the display device. Typically, an alphanumeric input device 722, such as a keyboard with alphanumeric, function and other keys, may be coupled to the bus for communicating information and command selections to the processor. A cursor control input device 723, such as a mouse, a trackball, or cursor direction keys can be coupled to the bus for communicating direction information and command selections to the processor and to control cursor movement on the display 721.

A communication device 725 is also coupled to the bus 701. The communication device 725 may include a modem, a network interface card, or other well known interface devices, such as those used for coupling to Ethernet, token ring, or other types of physical attachment for purposes of providing a communication link to support a local or wide area network (LAN or WAN), for example. In this manner, the computer system may also be coupled to a number of clients or servers via a conventional network infrastructure, including an intranet or the Internet, for example.

A lesser or more equipped computer system than the example described above may be preferred for certain implementations. Therefore, the configuration of the exemplary computer system 700 will vary from implementation to implementation depending upon numerous factors, such as price constraints, performance requirements, technological improvements, or other circumstances. The duty cycle monitor circuit, XOR gate, measurement process and clock circuit such as those shown and described herein may be incorporated into any of the clocked devices in the computer system shown in FIG. 7 or in other devices not shown in the present application.

A lesser or more complicated duty cycle monitor circuit, XOR gate, measurement process and clock circuit may be used than those shown and described herein. Therefore, the configurations may vary from implementation to implementation depending upon numerous factors, such as price constraints, performance requirements, technological improvements, or other circumstances. Embodiments of the invention may also be applied to other types of systems that use different clock sources and different devices than those shown and described herein.

In the description above, numerous specific details are set forth. However, it is understood that embodiments of the invention may be practiced without these specific details. For example, well-known equivalent materials may be substituted in place of those described herein, and similarly, well-known equivalent techniques may be substituted in place of the particular processing techniques disclosed. In other instances, well-known circuits, structures and techniques have not been shown in detail to avoid obscuring the understanding of this description.

While the embodiments of the invention have been described in terms of several examples, those skilled in the art may recognize that the invention is not limited to the embodiments described, but may be practiced with modification and alteration within the spirit and scope of the appended claims. The description is thus to be regarded as illustrative instead of limiting.

What is claimed is:

1. An apparatus comprising:
a clock signal selector to alternately select the high or the low phase of an input clock signal;
a sweep circuit to sweep a timing parameter through a range; and
a latch to compare the clock signal to the timing parameter and generate a result.

2. The apparatus of claim 1, wherein the clock signal selector comprises a conditional invert circuit.

3. The apparatus of claim 2, wherein the conditional invert circuit comprises an XOR gate.

4. The apparatus of claim 2, wherein the conditional invert circuit comprises a line of inverters coupled to pass gates, the output of one inverter of the line of inverters being used as a clock output and the output of a next inverter in the line of inverters being used as an invert clock output.

5. The apparatus of claim 1 wherein the sweep circuit comprises a variable delay line.

6. The apparatus of claim 1, wherein the sweep circuit comprises a variable frequency generator.

7. The apparatus of claim 1, wherein the latch is coupled to the clock signal selector through an inverter and to the sweep circuit to compare the inverter output to the sweep circuit output to generate the result.

8. A method comprising:
selecting one of a high phase or a low phase of a clock signal;
sweeping a timing parameter through a range;
comparing the selected phase of the clock signal to the timing parameter to measure the duration of the selected phase;
selecting the other of the high phase of the low phase of the clock signal;
sweeping the timing parameter through a range;
comparing the selected phase of the clock signal to the timing parameter to measure the duration of the other phase; and
determining the duty cycle offset of the clock signal using the measurements.

9. The method of claim 8 wherein the timing parameter is frequency.

10. The method of claim 8, wherein the timing parameter is delay.

11. The method of claim 10, wherein sweeping comprises sweeping through a set of coarse delay steps, the method further comprising after sweeping, selecting a best coarse delay and then sweeping through a set of fine delay steps.

12. The method of claim 8, further comprising fixing a setup margin before sweeping the timing parameter.

13. The method of claim 8, further comprising adjusting the duty cycle of the clock signal using the determined duty cycle offset.

14. An apparatus comprising a machine-readable medium including instructions that when executed by the machine cause the machine to perform operations comprising:
selecting one of a high phase or a low phase of a clock signal;
sweeping a timing parameter through a range;
comparing the selected phase of the clock signal to the timing parameter to measure the duration of the selected phase;
selecting the other of the high phase of the low phase of the clock signal;
sweeping the timing parameter through a range;
comparing the selected phase of the clock signal to the timing parameter to measure the duration of the other phase; and
determining the duty cycle offset of the clock signal using the measurements.

15. The medium of claim 14, wherein the instructions for sweeping comprise instructions for sweeping through a set of coarse delay steps, the medium further comprising instructions that when executed by the machine cause the machine to perform operations further comprising after sweeping, selecting a best coarse delay and then sweeping through a set of fine delay steps.

16. The medium of claim 14, wherein the instructions further comprise instructions for fixing a setup margin before sweeping the timing parameter

17. The medium of claim 14, further comprising instructions for adjusting the duty cycle of the clock signal using the determined duty cycle offset.

18. A computer system comprising:
a source clock;
a bus; and
a processor to communicate data with external components through the bus based on a signal from the source clock, the processor including a duty cycle monitor to monitor the duty cycles of a clock based on the signal from the source clock, the duty cycle monitor including a clock signal selector to alternately select the high or the low phase of an input clock signal, a sweep circuit to sweep a timing parameter through a range, and a latch to compare the clock signal to the timing parameter and generate a result.

19. The computer system of claim 18 wherein the sweep circuit comprises a variable delay line.

20. The apparatus of claim 18, wherein the latch is coupled to the clock signal selector through an inverter and to the sweep circuit to compare the inverter output to the sweep circuit output to generate the result.
